(19) United States
(12) Patent Application Publication
(10) Pub. No.: US 2026/0112427 A1
(43) Pub. Date: Apr. 23, 2026

(54) MEMORY DEVICE AND METHOD OF OPERATING THE SAME

(71) Applicant: SK hynix Inc., Gyeonggi-do (KR)

(72) Inventor: Hee Youl LEE, Gyeonggi-do (KR)

(21) Appl. No.: 19/172,661

(22) Filed: Apr. 8, 2025

(30) Foreign Application Priority Data
Oct. 21, 2024 (KR) 10-2024-0143911

(51) Int. Cl. G11C 16/34; G11C 16/24; G11C 16/26; G11C 16/30

(52) U.S. Cl. CPC G11C 16/3459; G11C 16/24; G11C 16/26; G11C 16/30

(57) ABSTRACT

Provided herein may be a memory device and a method of operating the same. The memory device may include a memory block connected to a plurality of word lines; a voltage generator configured to generate, during a program operation on the memory block, a program voltage and a plurality of program verify voltages to be applied to a selected word line among the word lines, and generate, during a read operation a plurality of read voltages to be applied to the selected word line; and a control logic configured to control the voltage generator. During a program verify operation of the program operation, the voltage generator generates the plurality of program verify voltages according to a verify voltage ascending method during a program verify operation of the program operation. During the read operation, the voltage generator generates the read voltages according to a read voltage descending method.

### CROSS-REFERENCE TO RELATED APPLICATION

The present application claims priority under 35 U.S.C. § 119(a) to Korean patent application number 10-2024-0143911 filed on Oct. 21, 2024, the entire disclosure of which is incorporated herein by reference.

### BACKGROUND

### 1. Technical Field

Various embodiments of the present disclosure generally relate to an electronic device, and more particularly to a memory device and a method of operating the memory device.

### 2. Related Art

A storage device is a device which stores data under the control of a host device, such as a computer or a smartphone. The storage device may include a memory device in which data is stored and a memory controller which controls the memory device. Memory devices are classified into a volatile memory device and a nonvolatile memory device.

The volatile memory device is a memory device in which data is stored only when power is supplied and in which stored data is lost when the supply of power is interrupted. Examples of the volatile memory device include a static random access memory (SRAM) and a dynamic random access memory (DRAM).

The nonvolatile memory device is a memory device in which stored data is retained even when the supply of power is interrupted. Examples of the nonvolatile memory device include a read only memory (ROM), a programmable ROM (PROM), an electrically programmable ROM (EPROM), an electrically erasable and programmable ROM (EEPROM), and a flash memory.

### SUMMARY

Various embodiments of the present disclosure are directed to a memory device and a method of operating the memory device, which can improve the threshold voltage distributions of memory cells and which can reduce internal current consumption (ICC) of the memory device and enhance the operation performance of the memory device.

An embodiment of the present disclosure may provide for a memory device. The memory device may include a memory block connected to a plurality of word lines; a voltage generator configured to generate, during a program operation on the memory block, a program voltage and a plurality of program verify voltages to be applied to a selected word line among the plurality of word lines, and generate, during a read operation on the memory block, a plurality of read voltages to be applied to the selected word line; and a control logic configured to control the voltage generator. During a program verify operation of the program operation, the voltage generator is configured to generate the plurality of program verify voltages according to a verify voltage ascending method in which the plurality of program verify voltages are sequentially generated in an order from a program verify voltage having a low level to a program verify voltage having a high level during a program verify operation of the program operation. During the read operation, the voltage generator is configured to generate the plurality of read voltages according to a read voltage descending method in which the plurality of read voltages are sequentially generated in an order from a read voltage having a high level to a read voltage having a low level during the read operation.

An embodiment of the present disclosure may provide for a method of operating a memory device. The method may include performing a program operation of sequentially performing a plurality of program loops, each including a program voltage apply operation and a program verify operation, on selected memory cells in response to a program command; and performing a read operation on the selected memory cells in response to a read command after the program operation is completed, wherein, during the program verify operation, a plurality of program verify voltages are applied to the selected memory cells according to a verify voltage ascending method in which the plurality of program verify voltages are sequentially applied to the selected memory cells in an order from a program verify voltage having a low level to a program verify voltage having a high level, and wherein, during the read operation, a plurality of read voltages are applied to the selected memory cells according to a read voltage descending method in which the plurality of read voltages are sequentially applied to the selected memory cells in an order from a read voltage having a high level to a read voltage having a low level.

An embodiment of the present disclosure may provide for a method of operating a memory device. The method may include performing a program operation of sequentially performing a plurality of program loops, each including a program voltage apply operation and a program verify operation, on selected memory cells in response to a program command; and performing a read operation on the selected memory cells in response to a read command after the program operation is completed, wherein, in response to a case in which all bit lines connected to the selected memory cells are simultaneously precharged during a bit line precharge operation of precharging the bit lines while the program verify operation is performed, a plurality of program verify voltages are applied to the selected memory cells according to a verify voltage ascending method in which the plurality of program verify voltages are sequentially applied to the selected memory cells in an order from a program verify voltage having a low level to a program verify voltage having a high level, and in response to a case in which part of the bit lines are selectively precharged during the bit line precharge operation, the plurality of program verify voltages are applied to the selected memory cells according to a verify voltage descending method in which the plurality of program verify voltages are sequentially applied to the selected memory cells in an order from a program verify voltage having a low level to a program verify voltage having a high level.

An embodiment of the present disclosure may provide for a method of operating a memory device. The method may include performing a program operation of sequentially performing a plurality of program loops, each including a program voltage apply operation and a program verify operation, on selected memory cells in response to a program command; and performing a read operation on the selected memory cells in response to a read command after the program operation is completed, wherein, in response to a case in which the program operation is performed in an internal current consumption (ICC) priority mode, a plurality of program verify voltages are applied, during the program verify operation, to the selected memory cells according to a verify voltage ascending method in which the plurality of program verify voltages are sequentially applied to the selected memory cells in an order from a program verify voltage having a low level to a program verify voltage having a high level, and wherein, in response to a case in which the program operation is performed in an operation performance priority mode, the plurality of program verify voltages are applied, during the program verify operation, to the selected memory cells according to a verify voltage descending method in which the plurality of program verify voltages are sequentially applied to the selected memory cells in an order from the program verify voltage having the high level to the program verify voltage having the low level.

### BRIEF DESCRIPTION OF THE DRAWINGS

FIG. 1 is a diagram for describing a memory system including a memory device according to an embodiment of the present disclosure.

FIG. 2 is a diagram for describing the structure of the memory device of FIG. 1.

FIG. 3 is a diagram illustrating an embodiment of a memory cell array of FIG. 2.

FIG. 4 is a circuit diagram for describing one of a plurality of memory blocks BLK1 to BLKz illustrated in FIG. 3.

FIG. 5 is a circuit diagram for describing memory cell strings illustrated in FIG. 4.

FIG. 6 is a diagram for describing the threshold voltage distributions of memory cells and data corresponding to the threshold voltage distributions.

FIG. 7 is a flowchart for describing a program operation and a read operation of a memory device according to an embodiment of the present disclosure.

FIGS. 8 and 9 are diagrams for describing a program operation according to an embodiment of the present disclosure.

FIGS. 10, 11, and 12 are waveform diagrams for describing a read operation according to an embodiment of the present disclosure.

FIG. 13 is a flowchart for describing a program operation and a read operation of a memory device according to an embodiment of the present disclosure.

FIG. 14 is a flowchart for describing a program operation and a read operation of a memory device according to an embodiment of the present disclosure.

FIG. 15 is a block diagram illustrating a memory card system including a memory system according to an embodiment of the present disclosure.

FIG. 16 is a block diagram illustrating a solid state drive (SSD) system including a memory system according to an embodiment of the present disclosure.

FIG. 17 is a block diagram illustrating a user system including a memory system according to an embodiment of the present disclosure.

### DETAILED DESCRIPTION

Specific structural or functional descriptions in the embodiments of the present disclosure introduced in this specification are provided to describe embodiments according to the concept of the present disclosure. The embodiments according to the concept of the present disclosure may be practiced in various forms, and should not be construed as being limited to the embodiments described in this specification.

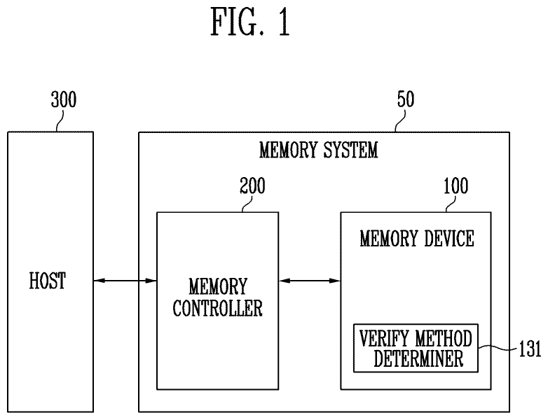

FIG. 1 is a diagram for describing a memory system 50 including a memory device according to an embodiment of the present disclosure.

Referring to FIG. 1, the memory system 50 may include a memory device 100 and a memory controller 200. The memory system 50 may be a device which stores data under the control of a host 300, such as a mobile phone, a smartphone, an MP3 player, a laptop computer, a desktop computer, a game console, a television (TV), a tablet PC, or an in-vehicle infotainment system.

The memory system 50 may be manufactured as any of various types of storage devices depending on a host interface that is a scheme for communication with the host 300. For example, the memory system 50 may be implemented as any of various types of storage devices, for example, a solid state disk (SSD), a multimedia card such as an MMC, an embedded MMC (eMMC), a reduced size MMC (RS-MMC), or a micro-MMC, a secure digital card such as an SD, a mini-SD, or a micro-SD, a universal serial bus (USB) storage device, a universal flash storage (UFS) device, a personal computer memory card international association (PCMCIA) card-type storage device, a peripheral component interconnection (PCI)-card type storage device, a PCI express (PCI-E) card-type storage device, a compact flash (CF) card, a smart media card, and a memory stick.

The memory system 50 may be manufactured in any of various types of package forms. For example, the memory system 50 may be manufactured in any of various types of package forms, such as package on package (POP), system in package (SIP), system on chip (SOC), multi-chip package (MCP), chip on board (COB), wafer-level fabricated package (WFP), and wafer-level stack package (WSP).

The memory device 100 may store data. The memory device 100 may be operated under the control of the memory controller 200. The memory device 100 may include a memory cell array (not illustrated) including a plurality of memory cells which store data.

Each of the memory cells may be implemented as a single-level cell (SLC) capable of storing one bit of data, a multi-level cell (MLC) capable of storing two bits of data, a triple-level cell (TLC) capable of storing three bits of data, or a quad-level cell (QLC) capable of storing four bits of data.

The memory cell array (not illustrated) may include a plurality of memory blocks. Each memory block may include a plurality of memory cells. One memory block may include a plurality of pages. In an embodiment, each page may be the unit by which data is stored in the memory device 100 or by which data stored in the memory device 100 is read. A memory block may be the unit by which data is erased.

In an embodiment, the memory device 100 may be a double data rate synchronous dynamic random access memory (DDR SDRAM), a low power double data rate fourth generation (LPDDR4) SDRAM, a graphics double data rate (GDDR) SDRAM, a low power DDR (LPDDR) SDRAM, a Rambus DRAM (RDRAM), a NAND flash memory, a vertical NAND flash memory, a NOR flash memory, a resistive RAM (RRAM), a phase-change random access memory (PRAM), a magnetoresistive RAM (MRAM), a ferroelectric RAM (FRAM), a spin transfer torque RAM (STT-RAM), or the like. In the present specification, for convenience of description, description will be made based on that the memory device 100 is a NAND flash memory.

The memory device 100 may receive a command and an address from the memory controller 200, and may access the area of the memory cell array, selected by the address. The memory device 100 may perform an operation indicated by the command on the area selected by the address. For example, the memory device 100 may perform a write operation (program operation), a read operation, and an erase operation. During a write operation, the memory device 100 may program data to the area selected by the address. During a read operation, the memory device 100 may read data from the area selected by the address. During an erase operation, the memory device 100 may erase data stored in the area selected by the address.

In an embodiment, the memory device 100 may include a verify method determiner 131. The verify method determiner 131 may determine whether to perform a program verify operation using a verify voltage ascending method or perform a program verify operation using a verify voltage descending method during a program verify operation in which a plurality of program verify voltages are sequentially applied to memory cells while the program operation is performed. The verify voltage ascending method may be performed such that program operations are sequentially completed in the order from memory cells desired to be programmed to a low program state during the program verify operation, thus improving the threshold voltage distributions of the memory cells. Also, the verify voltage descending method may be performed such that program verify voltages are generated in the order from a high program verify voltage to a low program verify voltage, thus improving the speed of a voltage generation operation, with the result that the speed of a program verify operation may be improved.

For example, the verify voltage ascending method may be a program verify method in which, after a program voltage is applied to a selected word line, a plurality of program verify voltages are sequentially applied to the selected word line in the order from a program verify voltage having a low level to a program verify voltage having a high level. Further, the verify voltage descending method may be a program verify method in which, after a program voltage is applied to a selected word line, a plurality of program verify voltages are sequentially applied to the selected word line in the order from a program verify voltage having a high level to a program verify voltage having a low level.

In a case where a bit line precharge operation is performed using an all-bit-line (ABL) precharge method in which all bit lines connected to a selected memory block are simultaneously precharged during the bit line precharge operation of the program verify operation, the verify method determiner 131 may determine to perform the program verify operation using the above-described verify voltage ascending method. On the other hand, in a case where only some bit lines among bit lines connected to the selected memory block are selectively and simultaneously precharged during the bit line precharge operation, the verify method determiner 131 may determine to perform the program verify operation using the above-described verify voltage descending method.

In an embodiment, in a case where a command is received from the host 300 to reduce internal current consumption (ICC) of the memory device 100, the verify method determiner 131 may determine to perform the program verify operation using the above-described verify voltage ascending method. On the other hand, when a command is received from the host 300 to improve the performance of the memory device 100, the verify method determiner 131 may determine to perform the program verify operation using the above-described verify voltage descending method. That is, when the memory device 100 is in an ICC priority mode, the program verify operation may be determined to be performed using the verify voltage ascending method, whereas when the memory device 100 is in an operation performance priority mode, the program verify operation may be determined to be performed using the verify voltage descending method.

The memory controller 200 may control the overall operation of the memory system 50.

When power is applied to the memory system 50, the memory controller 200 may run firmware (FW). When the memory device 100 is a flash memory device, the firmware (FW) may include a host interface layer (HIL) which controls communication with the host 300, a flash translation layer (FTL) which controls communication between the host 300 and the memory device 100, and a flash interface layer (FIL) which controls communication with the memory device 100.

In an embodiment, the memory controller 200 may receive data and a logical block address (LBA) from the host 300, and may translate the logical block address (LBA) into a physical block address (PBA) indicating the address of memory cells which are included in the memory device 100 and in which data is to be stored. In the present specification, a logical block address (LBA) and a “logical address” may be used interchangeably with each other. In the present specification, a physical block address (PBA) and a “physical address”may be used interchangeably with each other.

The memory controller 200 may control the memory device 100 to perform a write operation, a read operation or an erase operation according to a request received from the host 300. During a write operation, the memory controller 200 may provide a write command, a physical block address, and data to the memory device 100. During a read operation, the memory controller 200 may provide a read command and a physical block address to the memory device 100. During an erase operation, the memory controller 200 may provide an erase command and a physical block address to the memory device 100.

In an embodiment, the memory controller 200 may independently generate a command, an address, and data regardless of whether a request from the host 300 is received, and may transmit the command, address, and data to the memory device 100. For example, the memory controller 200 may provide the memory device 100 with commands, addresses, and data which are required for performing read operations and write operations associated with performance of wear leveling, read reclaim, garbage collection, etc.

In an embodiment, the memory controller 200 may control at least two memory devices 100. In this case, the memory controller 200 may control the memory devices 100 depending on an interleaving scheme to improve operation performance. The interleaving scheme may be a scheme for controlling the memory devices 100 so that the operations of at least two memory devices 100 overlap each other.

The host 300 may communicate with the memory system 50 using at least one of various communication standards or interfaces such as universal serial bus (USB), serial AT attachment (SATA), serial attached SCSI (SAS), high speed Interchip (HSIC), small computer system Interface (SCSI), peripheral component interconnection (PCI), PCI express (PCIe), nonvolatile memory express (NVMe), universal flash storage (UFS), secure digital (SD), multimedia card (MMC), embedded MMC (eMMC), dual in-line memory module (DIMM), registered DIMM (RDIMM), and load reduced DIMM (LRDIMM) communication methods.

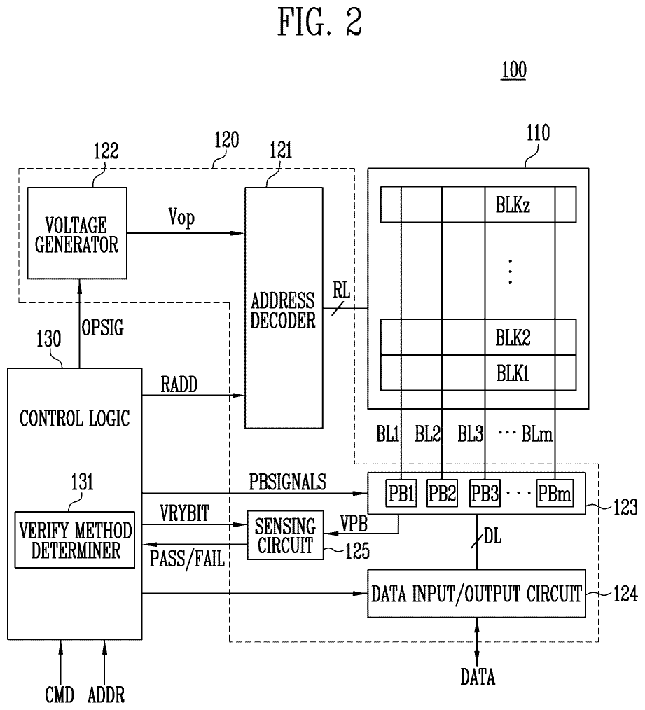

FIG. 2 is a diagram for describing the structure of the memory device of FIG. 1.

Referring to FIG. 2, the memory device 100 may include a memory cell array 110, a peripheral circuit 120, and a control logic 130.

The memory cell array 110 may include a plurality of memory blocks BLK1 to BLKz. The plurality of memory blocks BLK1 to BLKz are connected to an address decoder 121 through row lines RL. The plurality of memory blocks BLK1 to BLKz may be connected to a page buffer group 123 through bit lines BL1 to BLm. Each of the memory blocks BLK1 to BLKz may include a plurality of memory cells. In an embodiment, the plurality of memory cells may be nonvolatile memory cells. Memory cells connected to the same word line among the plurality of memory cells are defined as one page. The memory cell array 110 may be composed of a plurality of pages. In accordance with an embodiment of the present disclosure, each of the memory blocks BLK1 to BLKz included in the memory cell array 110 may include a plurality of dummy cells. For the dummy cells, one or more dummy cells may be connected in series between a drain select transistor and memory cells and between a source select transistor and memory cells.

Each of the memory cells of the memory device 100 may be implemented as a single-level cell (SLC) capable of storing one bit of data, a multi-level cell (MLC) capable of storing two bits of data, a triple-level cell (TLC) capable of storing three bits of data, or a quad-level cell (QLC) capable of storing four bits of data.

The peripheral circuit 120 may drive the memory cell array 110. In an example, the peripheral circuit 120 may drive the memory cell array 110 to perform a program operation, a read operation, and an erase operation under the control of the control logic 130. In an example, the peripheral circuit 120 may apply various driving voltages (operating voltages) Vop to the row lines RL and the bit lines BL1 to BLm or discharge the applied voltages under the control of the control logic 130.

The peripheral circuit 120 may include the address decoder 121, a voltage generator 122, the page buffer group 123, a data input/output circuit 124, and a sensing circuit 125.

The address decoder 121 is connected to the memory cell array 110 through the row lines RL. The row lines RL may include drain select lines, word lines, source selection lines, and a common source line. In accordance with an embodiment of the present disclosure, the word lines may include normal word lines and dummy word lines. In accordance with an embodiment of the present disclosure, the row lines RL may further include a pipe select line.

The address decoder 121 may be operated under the control of the control logic 130. The address decoder 121 receives addresses ADDR from the control logic 130.

The address decoder 121 may decode a block address among the received addresses ADDR. The address decoder 121 may select at least one of the memory blocks BLK1 to BLKz according to the decoded block address. The address decoder 121 may decode a row address RADD among the received addresses ADDR. The address decoder 121 may select at least one word line WL of the selected memory block by applying voltages supplied from the voltage generator 122 to the at least one word line WL according to the decoded row address RADD.

During a program operation, the address decoder 121 may apply a program voltage to the selected word line and apply a pass voltage having a level lower than that of the program voltage to unselected word lines. During a program verify operation, the address decoder 121 may apply a program verify voltage to the selected word line and apply a pass voltage having a level higher than that of the program verify voltage to the unselected word lines.

During a read operation, the address decoder 121 may apply a read voltage to the selected word line and apply a pass voltage having a level higher than that of the read voltage to the unselected word lines.

An erase operation of the memory device 100 may be performed on a memory block basis. During the erase operation, addresses ADDR input to the memory device 100 include a block address. The address decoder 121 may decode the block address and select one memory block according to the decoded block address. During the erase operation, the address decoder 121 may apply a ground voltage to word lines connected to the selected memory block.

The address decoder 121 may decode a column address among the received addresses ADDR. The decoded column address may be transferred to the page buffer group 123. In an embodiment, the address decoder 121 may include components, such as a row decoder, a column decoder, and an address buffer.

The voltage generator 122 may generate a plurality of driving voltages Vop using an external supply voltage that is supplied to the memory device 100. The voltage generator 122 may be operated under the control of the control logic 130.

In an embodiment, the voltage generator 122 may generate an internal supply voltage by regulating the external supply voltage. The internal supply voltage generated by the voltage generator 122 may be used as a driving voltage for the memory device 100.

In an embodiment, the voltage generator 122 may generate various driving voltages Vop that are used for program, read, and erase operations in response to an operation signal OPSIG. The voltage generator 122 may generate the plurality of driving voltages Vop using the external supply voltage or the internal supply voltage. The voltage generator 122 may generate various voltages required by the memory device 100. For example, the voltage generator 122 may generate a plurality of erase voltages, a plurality of program voltages, a plurality of program verify voltages, a plurality of read voltages, and a plurality of pass voltages.

The voltage generator 122 may include a plurality of pumping capacitors for receiving the internal supply voltage to generate a plurality of driving voltages Vop having various voltage levels, and may generate the plurality of driving voltages Vop by selectively enabling the plurality of pumping capacitors under the control of the control logic 130.

In an embodiment, the voltage generator 122 may sequentially generate the plurality of program verify voltages to be applied to a selected word line during the program verify operation. In this case, the plurality of program verify voltages may be sequentially generated in the order from a program verify voltage having a low level to a program verify voltage having a high level, or in the order from a program verify voltage having a high level to a program verify voltage having a low level.

In an embodiment, the voltage generator 122 may generate a plurality of read voltages to be applied to a selected word line during a read operation. Here, the plurality of read voltages may be sequentially generated in the order from a read voltage having a high level to a read voltage having a low level.

The page buffer group 123 may include first to m-th page buffers PB1 to PBm. The first to m-th page buffers PB1 to PBm are connected to the memory cell array 110 through the first to m-th bit lines BL1 to BLm, respectively. The first to m-th page buffers PB1 to PBm are operated under the control of the control logic 130.

The first to m-th page buffers PB1 to PBm perform data communication with the data input/output circuit 124. During a program operation, the first to m-th page buffers PB1 to PBm may receive data DATA to be stored through the data input/output circuit 124 and data lines DL.

During a program operation, the first to m-th page buffers PB1 to PBm may transfer the data DATA to be stored, received through the data input/output circuit 124, to selected memory cells through the bit lines BL1 to BLm when a program pulse is applied to a selected word line. Memory cells in a selected page may be programmed based on the transferred data DATA. Memory cells connected to a bit line to which a program-enable voltage (e.g., a ground voltage) is applied may have increased threshold voltages. The threshold voltages of memory cells connected to a bit line to which a program-inhibit voltage (e.g., a supply voltage) is applied may be maintained. During a program verify operation, the first to m-th page buffers PB1 to PBm may read the data DATA stored in the selected memory cells from the selected memory cells through the bit lines BL1 to BLm.

During a read operation, the page buffer group 123 may read data DATA from the memory cells in the selected page through the bit lines BL1 to BLm, and may store the read data DATA in the first to m-th page buffers PB1 to PBm.

During an erase operation, the page buffer group 123 may allow the bit lines BL1 to BLm to float. In an embodiment, the page buffer group 123 may include a column select circuit.

The data input/output circuit 124 is connected to the first to m-th page buffers PB1 to PBm through the data lines DL. The data input/output circuit 124 may be operated under the control of the control logic 130.

The data input/output circuit 124 may include a plurality of input/output buffers (not illustrated) which receive input data DATA. During a program operation, the data input/output circuit 124 receives the data DATA to be stored from an external controller (not illustrated). During a read operation, the data input/output circuit 124 outputs the data DATA, received from the first to m-th page buffers PB1 to PBm included in the page buffer group 123, to the external controller.

During a read operation or a verify operation, the sensing circuit 125 may generate a reference current in response to an enable bit signal VRYBIT generated by the control logic 130, and may output a pass signal or a fail signal to the control logic 130 by comparing a sensing voltage VPB received from the page buffer group 123 with a reference voltage generated by the reference current. In an embodiment, the sensing circuit 125 may output the pass signal to the control logic 130 when a level of the sensing voltage VPB is less than a level of the reference voltage. Furthermore, the sensing circuit 125 may output the fail signal to the control logic 130 when the level of the sensing voltage VPB is greater than the level of the reference voltage.

The control logic 130 may be connected to the address decoder 121, the voltage generator 122, the page buffer group 123, the data input/output circuit 124, and the sensing circuit 125. The control logic 130 may control the overall operation of the memory device 100. The control logic 130 may be operated in response to a command CMD transmitted from an external device (e.g., a host).

The control logic 130 may control the peripheral circuit 120 by generating various types of signals in response to the command CMD and the addresses ADDR. For example, the control logic 130 may generate the operation signal OPSIG, the row address RADD, page buffer control signals PBSIGNALS, and the enable bit signal VRYBIT in response to the command CMD and the addresses ADDR. The control logic 130 may output the operation signal OPSIG to the voltage generator 122, output the row address RADD to the address decoder 121, output the page buffer control signals PBSIGNALS to the page buffer group 123, and output the enable bit signal VRYBIT to the sensing circuit 125. In addition, the control logic 130 may determine whether a verify operation has passed or failed in response to the pass signal PASS or the fail signal FAIL output from the sensing circuit 125.

The verify method determiner 131 illustrated in FIG. 1 may be included in the control logic 130.

The verify method determiner 131 may determine whether to perform a program verify operation using a verify voltage ascending method or perform a program verify operation using a verify voltage descending method during the program verify operation of the program operation, and may control the peripheral circuit 120 to perform the program verify operation depending on the determined verify method.

For example, during the program verify operation of the program operation, the verify method determiner 131 may determine to perform the program verify operation using the verify voltage ascending method in which the plurality of program verify voltages are sequentially applied in the order from a program verify voltage having a low level. During the read operation, the verify method determiner 131 may determine to perform the read operation using a method in which the plurality of read voltages are sequentially applied in the order from a read voltage having a high level.

In an embodiment, in a case where a bit line precharge operation is performed using the ABL precharge operation method during a bit line precharge operation of the program verify operation, the verify method determiner 131 may determine to perform the program verify operation using the above-described verify voltage ascending method. Further, in a case where a bit line precharge operation is performed using a method of selectively and simultaneously precharging only some bit lines rather than the ABL precharge operation method during the bit line precharge operation, the verify method determiner 131 may determine to perform the program verify operation using the above-described verify voltage descending method.

In an embodiment, in a case where there is a need to reduce ICC of the memory device 100, the verify method determiner 131 may determine to perform the program verify operation using the above-described verify voltage ascending method. On the other hand, in a case where there is a need to improve the performance of the memory device 100, the verify method determiner 131 may determine to perform the program verify operation using the above-described verify voltage descending method. The reduction of ICC of the memory device 100 or the improvement of performance of the memory device 100 may be determined according to a request from the host, and a command corresponding to the request from the host may be transferred to the memory device 100 through the memory controller 200 of FIG. 1.

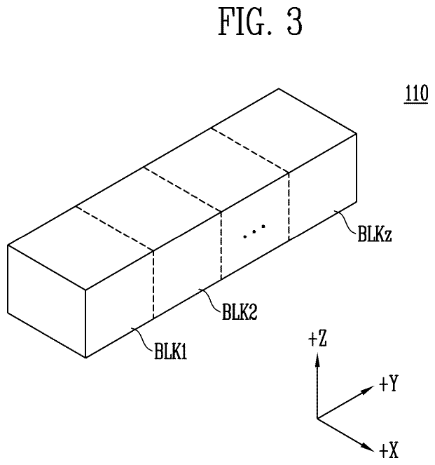

FIG. 3 is a diagram illustrating an embodiment of the memory cell array of FIG. 2.

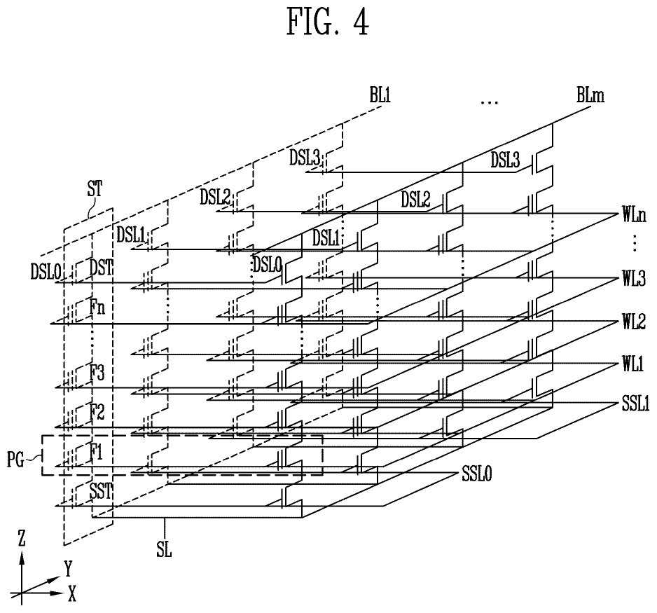

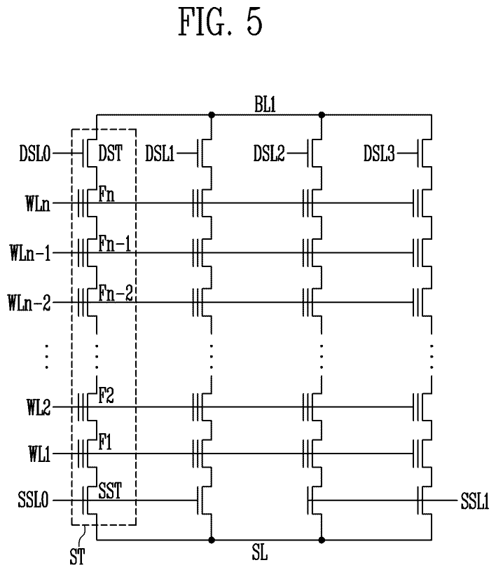

Referring to FIG. 3, the memory cell array 110 may include a plurality of memory blocks BLK1 to BLKz. Each of the memory blocks may have a three-dimensional (3D) structure. Each of the memory blocks may include a plurality of memory cells stacked on a substrate. The plurality of memory cells are arranged in +X, +Y, and +Z directions. The structure of each memory block will be described in detail below with reference to FIGS. 4 and 5.

FIG. 4 is a circuit diagram for describing one of a plurality of memory blocks BLK1 to BLKz illustrated in FIG. 3.

FIG. 5 is a circuit diagram for describing memory cell strings illustrated in FIG. 4.

Referring to FIGS. 4 and 5, each memory cell string ST may be connected between bit lines BL1 to BLm and a source line (i.e., common source line) SL. The memory cell string ST connected between the first bit line BL1 and the source line SL will be described by way of example.

The memory cell string ST may include a source select transistor SST, memory cells F1 to Fn, where n is a positive integer, and a drain select transistor DST which are connected in series between the source line SL and the first bit line BL1. Gates of source select transistors SST included in different memory cell strings ST connected to different bit lines BL1 to BLm may be connected to a first source select line SSL0 and may be connected to a second source select line SSL1. For example, source select transistors adjacent to each other in a second direction Y among source select transistors SST may be connected to the same source select line. For example, when the source select transistors SST are sequentially arranged in the second direction Y, gates of source select transistors SST, which are arranged in a first direction X from a first source select transistor SST and are included in different memory cell strings ST, and gates of source select transistors SST, which are arranged in the first direction X from a second source select transistor SST and are included in different memory cell strings ST, may be connected to the first source select line SSL0. Further, gates of source select transistors SST, which are arranged in the first direction X from a third source select transistor SST and are included in different memory cell strings ST, and gates of source select transistors SST, which are arranged in the first direction X from a fourth source select transistor SST and are included in different memory cell strings ST, may be connected to the second source select line SSL1.

Gates of the memory cells F1 to Fn may be connected to the word lines WL1 to WLn, and gates of the drain select transistors DST may be connected to any of first to fourth drain select lines DSL0 to DSL3.

Gates of transistors arranged in the first direction X among the drain select transistors DST may be connected in common to the same drain select line (e.g., DSL0), but gates of transistors arranged in the second direction Y may be connected to different drain select lines DSL0 to DSL3. For example, when the drain select transistor DST are sequentially arranged in the second direction Y, gates of drain select transistors DST which are arranged in the first direction X from a first drain select transistor DST and are included in different memory cell strings ST may be connected to the first drain select line DSL0. Gates of drain select transistors DST arranged in the second direction Y from the drain select transistors DST connected to the first drain select line DSL0 may be sequentially connected to the second to fourth drain select lines DSL1 to DSL3. Therefore, in a selected memory block, memory cell strings ST connected to a selected drain select line may be selected, and memory cell strings ST connected to the remaining drain select lines, that is, unselected drain select lines, may be unselected. For example, when the first drain select line DSL0 is selected, memory cell strings connected to the first drain select line DSL0 may be the selected memory cell strings, and memory cell strings connected to the second to fourth drain select lines DSL1 to DSL3 may be the unselected memory cell strings. Further, the first drain select line DSL0 may be the selected drain select line, and the second to fourth drain select lines DSL1 to DSL3 may be the unselected drain select lines. Furthermore, when the first drain select line DSL0 is selected, the first source select line SSL0 may be a selected source select line, and the second source select line SSL1 may be an unselected source select line.

Memory cells connected to the same word line may form a single page (PG). Here, the page may refer to a physical page. For example, in the memory cell strings ST connected to the first bit line BL1 to the m-th bit line BLm, a group of memory cells connected in the first direction X in the same word line is referred to as a page (PG). For example, among the first memory cells F1 connected to the first word line WL1, memory cells arranged in the first direction X may form a single page (PG). Among the first memory cells F1 connected in common to the first word line WL1, memory cells arranged in the second direction Y may be divided into different pages. Therefore, when the first drain select line DSL0 is a selected drain select line and the first word line WL1 is a selected word line, a page connected to the first drain select line DSL0, among a plurality of pages connected to the first word line WL1, may be a selected page. Pages that are connected in common to the first word line WL1, but are connected to unselected second to fourth drain select lines DSL1 to DSL3 may be unselected pages.

In an embodiment, when memory cells are programmed according to a TLC scheme in which three bits of data are stored in each memory cell, data stored in one page may be multi-page data. For example, the multi-page data may include a plurality of logical pages. In detail, the plurality of logical pages may include a least significant bit (LSB) page, a central significant bit (CSB) page, and a most significant bit (MSB) page.

Although, in the drawings, one source select transistor SST and one drain select transistor DST are illustrated as being included in one memory cell string ST, a plurality of source select transistors SST and drain select transistors DST may be included in one memory cell string ST depending on the memory device. Furthermore, dummy cells may be included between the source select transistor SST, the memory cells F1 to Fn, and the drain select transistor DST depending on the memory device. Although the dummy cells do not store user data like normal memory cells F1 to Fn, the dummy cells may be used to improve electrical characteristics of each memory cell string ST.

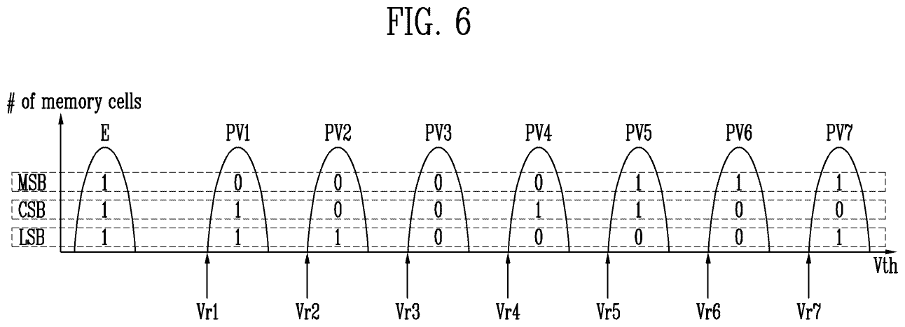

FIG. 6 is a diagram for describing the threshold voltage distributions of memory cells and data corresponding to the threshold voltage distributions.

In FIG. 6, a horizontal axis of the graph denotes the threshold voltages Vth of memory cells, and a vertical axis thereof denotes the number of memory cells ( #of memory cells).

In FIG. 6, the description will be made based on that memory cells are programmed according to a TLC scheme in which one memory cell stores three bits of data. Referring to FIG. 6, the threshold voltages of a plurality of memory cells may be increased to threshold voltages corresponding to any of an erase state E and first to seventh program states PV1 to PV7 through a program operation. During the program verify operation, the memory device 100 may apply a program verify voltage to a word line connected to selected memory cells, detect currents changed on bit lines connected to the selected memory cells, sense data stored in the selected memory cells, and verify whether the selected memory cells have been programmed to target threshold voltage values or higher during the program operation.

Thereafter, the memory device 100 may perform a read operation of obtaining data stored in memory cells. In detail, when a read voltage is applied to a word line connected to selected memory cells among the plurality of memory cells, the memory device 100 may detect currents changed on bit lines connected to the selected memory cells, and may then sense data stored in the selected memory cells. The data stored in the memory cells may vary depending on the program states of the memory cells. In detail, different pieces of data may be stored in the memory cells depending on the state to which the threshold voltages of the memory cells correspond among the erase state E and the first to seventh program states PV1 to PV7.

In an embodiment, the memory device 100 may perform a read operation on each of a plurality of logical pages using a plurality of read voltages. The plurality of logical pages may include an LSB page, a CSB page, and an MSB page. For example, as shown in FIG. 6, when the LSB page corresponding to the erase state E and the first to seventh program states PV1 to PV7 is 11100001, a read operation may be performed on the LSB page using a third read voltage Vr3 and a seventh read voltage Vr7 for distinguishing 1 from 0. Also, when the CSB page corresponding to the erase state E and the first to seventh program states PV1 to PV7 is 11001100, a read operation may be performed on the CSB page using a second read voltage Vr2, a fourth read voltage Vr4, and a sixth read voltage Vr6 for distinguishing 1 from 0. Furthermore, when the MSB page corresponding to the erase state E and the first to seventh program states PV1 to PV7 is 10000111, a read operation may be performed on the MSB page using a first read voltage Vr1 and a fifth read voltage Vr5 for distinguishing 1 from 0.

In an embodiment, bits included in the LSB page, the CSB page, and the MSB page may be stored as values different from those illustrated in FIG. 6. In this case, the read voltages for performing the read operation on the LSB page, the CSB page, and the MSB page may vary. For example, although, in FIG. 6, the case where the number of read voltages used for the read operation on the LSB page is 2 has been described, the read operation may be performed using three read voltages depending on the bits included in the LSB page. That is, the levels and number of read voltages for distinguishing 1 from 0 may vary depending on the bits included in the LSB page, the CSB page, and the MSB page.

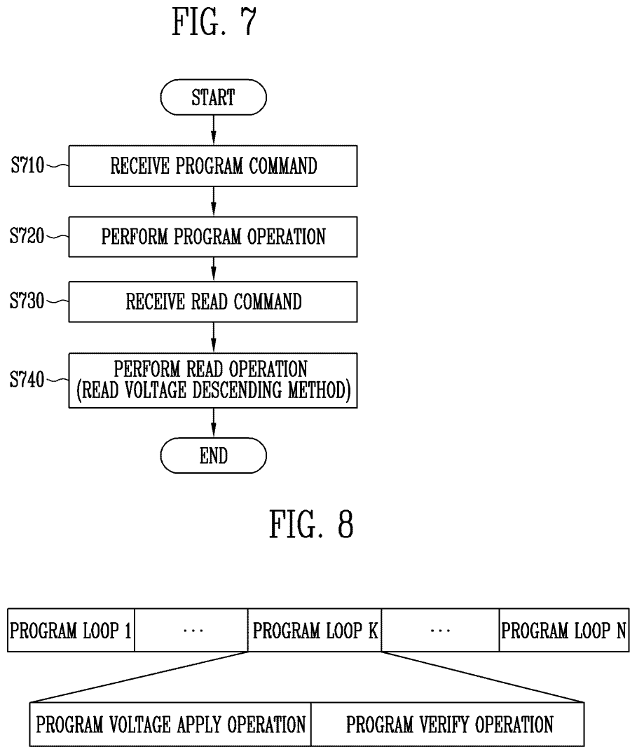

FIG. 7 is a flowchart for describing a program operation and a read operation of the memory device 100 according to an embodiment of the present disclosure.

At operation S710, the memory controller 200 may generate and output a program command for controlling a program operation of the memory device 100 according to a request from the host 300, and the memory device 100 may receive the program command from the memory controller 200. The memory controller 200 may provide the program command, a physical block address, and data to the memory device 100.

At operation S720, the memory device 100 may perform a program operation in response to the received program command.

The program operation may include a plurality of program loops, each including a program voltage apply operation and a program verify operation.

The verify method determiner 131 of the memory device 100 may determine to perform the program verify operation of each of the plurality of program loops included in the program operation using a verify voltage ascending method, and may control the peripheral circuit 120 to perform the program verify operation depending on the determined verify voltage ascending method.

The first to m-th page buffers PB1 to PBm receive data to be programmed DATA through the data input/output circuit 124 and temporarily store the received data. During the program voltage apply operation, the first to m-th page buffers PB1 to PBm may apply a program-enable voltage (e.g., a ground voltage) or a program-inhibit voltage (e.g., a supply voltage) to the bit lines BL1 to BLm based on the temporarily stored data.

During the program voltage apply operation, the voltage generator 122 may generate and output a program voltage and a pass voltage in response to an operation signal OPSIG.

During the program voltage apply operation, the address decoder 121 may apply the program voltage generated by the voltage generator 122 to a selected word line and apply the pass voltage generated by the voltage generator 122 to unselected word lines.

During the program verify operation, the voltage generator 122 may sequentially generate a plurality of program verify voltages in response to the operation signal OPSIG, and may generate the program verify voltages in the order from a program verify voltage having a low level to a program verify voltage having a high level.

The address decoder 121 may sequentially apply the plurality of program verify voltages generated by the voltage generator 122 to the selected word line and apply the pass voltage generated by the voltage generator 122 to the unselected word lines.

During the program verify operation, the first to m-th page buffers PB1 to PBm may sense data, stored in the selected memory cells, from the selected memory cells through the bit lines BL1 to BLm whenever the program verify voltage is applied to the selected word line. The first to m-th page buffers PB1 to PBm may generate and output a sensing voltage VPB based on the sensed data and the temporarily stored data to be programmed.

During the program verify operation, the sensing circuit 125 may generate a reference current in response to an enable bit signal VRYBIT generated by the control logic 130, and may output a pass signal PASS or a fail signal FAIL to the control logic 130 by comparing a sensing voltage VPB received from the page buffer group 123 with a reference voltage generated by the reference current. In an embodiment, the sensing circuit 125 may output the pass signal to the control logic 130 when a level of the sensing voltage VPB is less than a level of the reference voltage. The control logic 130 may determine whether the program operation has passed or failed based on the pass signal PASS or the fail signal FAIL.

After the above-described program operation is terminated, the memory controller 200 may generate and output a read command for controlling a read operation of the memory device 100 according to a request from the host 300, and the memory device 100 may receive the read command from the memory controller 200 at operation S730. The memory controller 200 may provide the read command and a physical block address to the memory device 100.

At operation S740, the memory device 100 may perform a read operation in response to the received read command.

The verify method determiner 131 of the memory device 100 may control the peripheral circuit 120 to perform the read operation using a read voltage descending method in which a plurality of read voltages are applied in the order from a read voltage having a high level to a read voltage having a low level.

For example, during the read operation, the voltage generator 122 may sequentially generate a plurality of read voltages in response to the operation signal OPSIG, and may generate the read voltages in the order from a read voltage having a high level to a read voltage having a low level.

The address decoder 121 may sequentially apply the plurality of read voltages generated by the voltage generator 122 to the selected word line and apply the pass voltage generated by the voltage generator 122 to the unselected word lines.

The first to m-th page buffers PB1 to PBm may sense data stored in the memory cells from the selected memory cells through the bit lines BL1 to BLm whenever a read verify voltage is applied to the selected word line, and may output the sensed data to the memory controller 200 through the data input/output circuit 124.

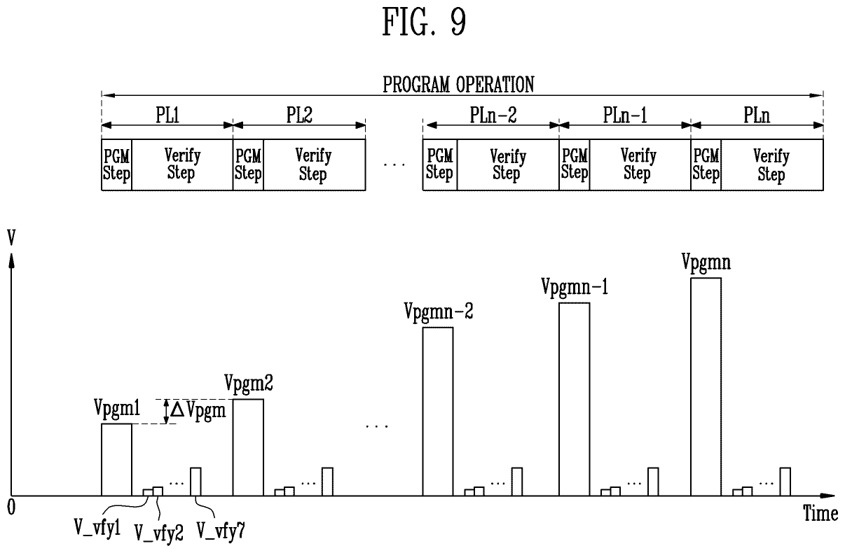

FIGS. 8 and 9 are diagrams for describing a program operation according to an embodiment of the present disclosure.

The operation S720 of FIG. 7 will be described in detail below with reference to FIGS. 8 and 9.

Referring to FIG. 8, the program operation may be performed in an Incremental Step Programming Pulse (ISPP) scheme including a plurality of program loops (i.e., program loop 1 to program loop N). The ISPP scheme may be a scheme for applying a program voltage that increases stepwise to a selected word line. Respective program loops may include program operations using different program voltages. For example, program loop 1 may include a program operation of applying a first program voltage to the selected word line, and program loop 2 may include a program operation of applying a second program voltage higher than the first program voltage by a step voltage to the selected word line. Whenever the program loop is sequentially performed, the program voltage may be stepwise increased by the step voltage.

Each program loop may include a program voltage apply operation of storing data in memory cells and a program verify operation of verifying the stored data. The program voltage apply operation may include a precharge period in which a voltage is applied to a bit line connected to cell strings, a program voltage apply period in which a program voltage is applied to the selected word line, and a discharge period in which voltages applied to word lines and bit lines are discharged.

In FIG. 9, the horizontal axis of a graph denotes time, and the vertical axis of the graph denotes voltage (V) applied to the selected word line.

In FIG. 9, the description will be made based on that memory cells are programmed according to a TLC scheme in which one memory cell stores three bits of data. However, the embodiments are not limited thereto, and it is possible to program the memory cells so that one memory cell stores data of two bits or less or data of four bits or more.

Referring to FIG. 9, the program operation may include a plurality of program loops PL1 to PLn. The memory device 100 may perform the plurality of program loops PL1 to PLn so that selected memory cells connected to a selected word line have threshold voltages corresponding to any of a plurality of program states. Each of the selected memory cells may have any of the plurality of program states as a target program state. For example, when one memory cell is programmed according to the TLC scheme, the memory device 100 may perform a final program operation including a plurality of program loops so that the selected memory cells have threshold voltages corresponding to any of an erase state E and first to seventh program states PV1 to PV7.

Each of the plurality of program loops PL1 to PLn may include a program voltage apply operation (PGM Step) and a program verify operation (Verify Step).

The program voltage apply operation (PGM Step) may be an operation of applying a program voltage to the selected word line to which the selected memory cells are connected. For example, the memory device 100 may apply a first program voltage Vpgm1 to the selected word line to which the selected memory cells are connected in the first program loop PL1. After the first program voltage Vpgm1 is applied to the selected word line, each of the selected memory cells may have a threshold voltage corresponding to the target program state.

The program verify operation (Verify Step) may be an operation of applying a verify voltage to the selected word line to which the selected memory cells are connected. The program verify operation (Verify Step) may be an operation of determining whether each of the selected memory cells has a threshold voltage corresponding to the target program state. The program verify operation (Verify Step) may be an operation of applying a verify voltage corresponding to the target program state of each of the selected memory cells.

In an embodiment, the memory device 100 may apply the first program voltage Vpgm1 to the selected word line to which the selected memory cells are connected, and thereafter apply first to seventh program verify voltages V_vfy1 to V_vfy7 to the selected word line, in the first program loop PL1. The memory device 100 may apply a program verify voltage corresponding to the target program state of each memory cell, among the first to seventh program verify voltages V_vfy1 to V_vfy7, to the selected word line. For example, the memory device 100 may perform a verify operation on the memory cells having the first program state PV1 as the target program state using the first program verify voltage V_vfy1 . The levels of the program verify voltages V_vfy1 to V_vfy7 may be increased in a direction from the first program verify voltage V_vfy1 to the seventh program verify voltage V_vfy7. In detail, among the levels of the program verify voltages V_vfy1 to V_vfy7, the level of the first program verify voltage V_vfy1 is the lowest, and the level of the seventh program verify voltage V_vfy7 may be the highest. The number of program verify voltages is not limited to the present embodiment.

The threshold voltages of memory cells having passed the program verify operation (Verify Step) by the program verify voltages V_vfy1 to V_vfy7, respectively, may be determined to be the threshold voltages corresponding to the target program state. A program-inhibit voltage may be applied to the bit line connected to the memory cells having passed the program verify operation (Verify Step) in the second program loop PL2.

The threshold voltages of memory cells having failed the program verify operation (Verify Step) by the program verify voltages V_vfy1 to V_vfy7, respectively, may be determined not to be the threshold voltages corresponding to the target program state. The memory cells having failed the program verify operation (Verify Step) may perform the second program loop PL2. A program-enable voltage may be applied to the bit line connected to the memory cells having failed the program verify operation (Verify Step) in the second program loop PL2.

In the second program loop PL2, the memory device 100 may apply the second program voltage Vpgm2 higher than the first program voltage Vpgm1 by the step voltage ΔVpgm to the selected word line to which the selected memory cells are connected. Thereafter, the memory device 100 may perform the program verify operation (Verify Step) of the second program loop PL2 in the same manner as the program verify operation (Verify Step) of the first program loop PL1.

Thereafter, the memory device 100 may perform the next program loops a preset number of times in the same manner as the second program loop PL2.

In an embodiment, when the program operation is not completed within the program loops corresponding to the preset number of times, the program operation may fail. When the program operation is completed within the program loops corresponding to the preset number of times, the program operation may pass. Whether the program operation has been completed may be determined depending on whether all program verify operations (Verify Step) on the selected memory cells have passed. When the program verify operation (Verify Step) on all of the selected memory cells has passed, the next program loop may not be performed.

In an embodiment, the program voltage may be determined according to an Incremental Step Pulse Programming (ISPP) scheme. The level of the program voltage may be increased or decreased stepwise as the program loops PL1 to PLn are repeated. The number of applications of program voltages used in each of the program loops, the voltage levels of the program voltages, voltage application times of the program voltages, or the like may be determined in various forms under the control of the memory controller 200.

As described above, during the program verify operation of each of the plurality of program loops according to an embodiment of the present disclosure, the program verify operation may be performed using a verify voltage ascending method in which a plurality of program verify voltages are applied in the order from a program verify voltage having a low level to a program verify voltage having a high level.

As described above, in a case where the program verify operation is performed using the verify voltage ascending method, the program operation on the memory cells may be completed in the order from memory cells desired to be programmed to a program state in which a threshold voltage distribution is low to memory cells desired to be programmed to a program state in which a threshold voltage distribution is high. Further, a phenomenon in which threshold voltage distributions of memory cells programmed to a low program state are changed to program pass during a program voltage apply operation and a program verify operation on memory cells desired to be programmed to a high program state may be improved.

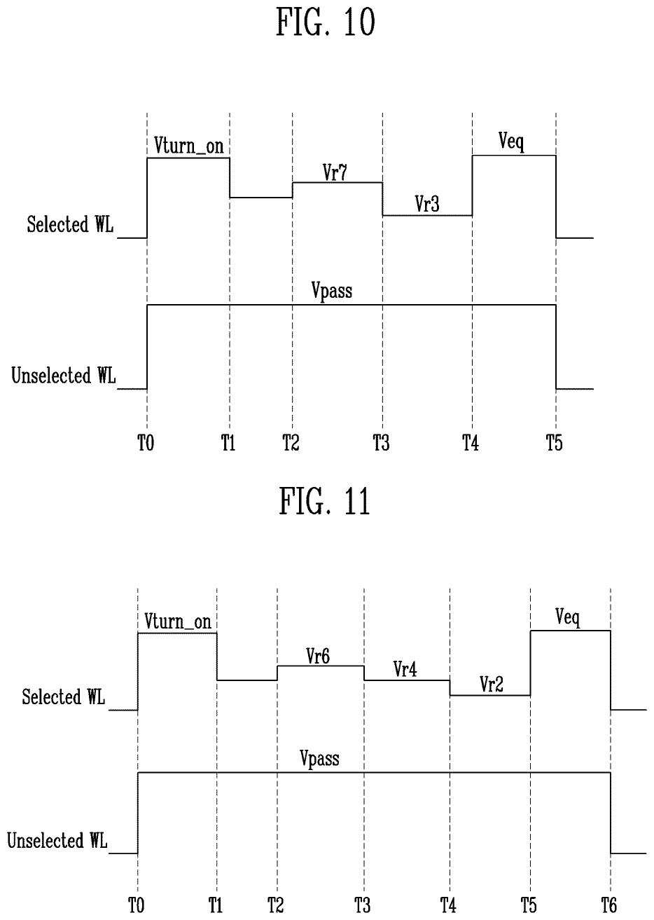

FIGS. 10, 11, and 12 are waveform diagrams for describing a read operation according to an embodiment of the present disclosure.

In an embodiment of the present disclosure, the description will be made based on that memory cells are programmed according to a TLC scheme in which one memory cell stores three bits of data. When the memory cells are programmed according to the TLC scheme, the read operation may be sequentially performed in the order of a read operation on an LSB page, a read operation on a CSB page, and a read operation on an MSB page.

The above-described operation S740 of FIG. 7 will be described in detail below with reference to FIGS. 10, 11 and 12.

The read operation on the LSB page will be described below with reference to FIG. 10.

During a period from T0 to T1, the voltage generator 122 may generate a turn-on voltage Vturn_on to be applied to a selected word line Selected WL and a pass voltage Vpass to be applied to unselected word lines Unselected WL, and the address decoder 121 may respectively apply the turn-on voltage Vturn_on and the pass voltage Vpass, generated by the voltage generator 122, to the selected word line Selected WL and the unselected word lines Unselected WL of a selected memory block (e.g., BLK1).

During a period from T1 to T2, the voltage generator 122 may discharge the potential of the selected word line Selected WL to a certain level by disabling the turn-on voltage Vturn_on generation operation.

During a period from T2 to T3, the voltage generator 122 may generate a seventh read voltage Vr7 for a certain time, and the address decoder 121 may apply the seventh read voltage Vr7, generated by the voltage generator 122, to the selected word line Selected WL. The page buffer group 123 may read data DATA from the memory cells connected to the selected word line Selected WL through the bit lines BL1 to BLm, and may store the read data DATA in the first to m-th page buffers PB1 to PBm.

During a period from T3 to T4, the voltage generator 122 may generate a third read voltage Vr3, and the address decoder 121 may apply the third read voltage Vr3, generated by the voltage generator 122, to the selected word line Selected WL. The page buffer group 123 may read data DATA from the memory cells connected to the selected word line Selected WL through the bit lines BL1 to BLm, and may store the read data DATA in the first to m-th page buffers PB1 to PBm.

During a period from T4 to T5, the voltage generator 122 may generate an equalizing voltage Veq, and the address decoder 121 may apply the equalizing voltage Veq, generated by the voltage generator 122, to the selected word line Selected WL. The equalizing voltage Veq may have the same level as the pass voltage Vpass. Thereafter, the voltage generator 122 may be disabled to stop generating the equalizing voltage Veq and the pass voltage Vpass, and the address decoder 121 may discharge the potentials of all word lines of the selected memory block BLK1.

The read operation on the CSB page will be described below with reference to FIG. 11.

During a period from T0 to T1, the voltage generator 122 may generate a turn-on voltage Vturn_on to be applied to a selected word line Selected WL and a pass voltage Vpass to be applied to unselected word lines Unselected WL, and the address decoder 121 may respectively apply the turn-on voltage Vturn_on and the pass voltage Vpass, generated by the voltage generator 122, to the selected word line Selected WL and the unselected word lines Unselected WL of a selected memory block (e.g., BLK1).

During a period from T1 to T2, the voltage generator 122 may discharge the potential of the selected word line Selected WL by disabling the turn-on voltage Vturn_on generation operation.

During a period from T2 to T3, the voltage generator 122 may generate a sixth read voltage Vr6 for a certain time, and the address decoder 121 may apply the sixth read voltage Vr6, generated by the voltage generator 122, to the selected word line Selected WL. The page buffer group 123 may read data DATA from the memory cells connected to the selected word line Selected WL through the bit lines BL1 to BLm, and may store the read data DATA in the first to m-th page buffers PB1 to PBm.

During a period from T3 to T4, the voltage generator 122 may generate a fourth read voltage Vr4 for a certain time, and the address decoder 121 may apply the fourth read voltage Vr4, generated by the voltage generator 122, to the selected word line Selected WL. The page buffer group 123 may read data DATA from the memory cells connected to the selected word line Selected WL through the bit lines BL1 to BLm, and may store the read data DATA in the first to m-th page buffers PB1 to PBm.

During a period from T4 to T5, the voltage generator 122 may generate a second read voltage Vr2, and the address decoder 121 may apply the second read voltage Vr2, generated by the voltage generator 122, to the selected word line Selected WL. The page buffer group 123 may read data DATA from the memory cells connected to the selected word line Selected WL through the bit lines BL1 to BLm, and may store the read data DATA in the first to m-th page buffers PB1 to PBm.

During a period from T5 to T6, the voltage generator 122 may generate an equalizing voltage Veq, and the address decoder 121 may apply the equalizing voltage Veq, generated by the voltage generator 122, to the selected word line Selected WL. The equalizing voltage Veq may have the same level as the pass voltage Vpass. Thereafter, the voltage generator 122 may be disabled to stop generating the equalizing voltage Veq and the pass voltage Vpass, and the address decoder 121 may discharge the potentials of all word lines of the selected memory block BLK1.

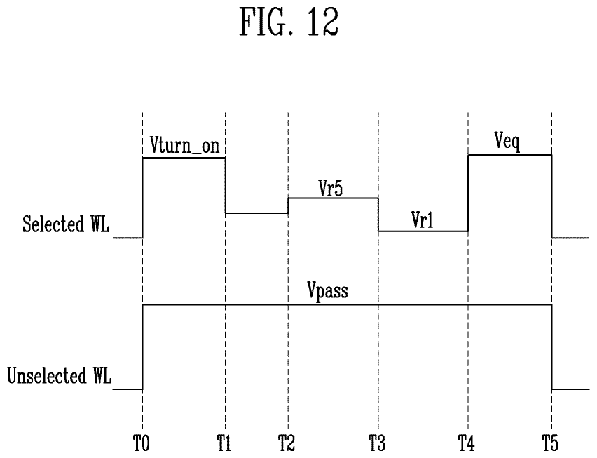

The read operation on the MSB page will be described below with reference to FIG. 12.

During a period from T0 to T1, the voltage generator 122 may generate a turn-on voltage Vturn_on to be applied to a selected word line Selected WL and a pass voltage Vpass to be applied to unselected word lines Unselected WL, and the address decoder 121 may respectively apply the turn-on voltage Vturn_on and the pass voltage Vpass, generated by the voltage generator 122, to the selected word line Selected WL and the unselected word lines Unselected WL of a selected memory block (e.g., BLK1).

During a period from T1 to T2, the voltage generator 122 may discharge the potential of the selected word line Selected WL by disabling the turn-on voltage Vturn_on generation operation.

During a period from T2 to T3, the voltage generator 122 may generate a fifth read voltage Vr5 for a certain time, and the address decoder 121 may apply the fifth read voltage Vr5, generated by the voltage generator 122, to the selected word line Selected WL. The page buffer group 123 may read data DATA from the memory cells connected to the selected word line Selected WL through the bit lines BL1 to BLm, and may store the read data DATA in the first to m-th page buffers PB1 to PBm.

During a period from T3 to T4, the voltage generator 122 may generate a first read voltage Vr1, and the address decoder 121 may apply the first read voltage Vr1, generated by the voltage generator 122, to the selected word line Selected WL. The page buffer group 123 may read data DATA from the memory cells connected to the selected word line Selected WL through the bit lines BL1 to BLm, and may store the read data DATA in the first to m-th page buffers PB1 to PBm.

During a period from T4 to T5, the voltage generator 122 may generate an equalizing voltage Veq, and the address decoder 121 may apply the equalizing voltage Veq, generated by the voltage generator 122, to the selected word line Selected WL. The equalizing voltage Veq may have the same level as the pass voltage Vpass. Thereafter, the voltage generator 122 may be disabled to stop generating the equalizing voltage Veq and the pass voltage Vpass, and the address decoder 121 may discharge the potentials of all word lines of the selected memory block BLK1.

As described above, during the read operation according to an embodiment of the present disclosure, each of the read operation on the LSB page, the read operation on the CSB page, and the read operation on the MSB page may be performed using a read voltage descending method in which read voltages are applied in the order from a read voltage having a high level to a read voltage having a low level.

As described above, the method of operating the memory device according to an embodiment may apply a plurality of program verify voltages using a verify voltage ascending method during the program verify operation of the program operation, and may apply a plurality of read voltages using the read voltage descending method during the read operation performed after the program operation.

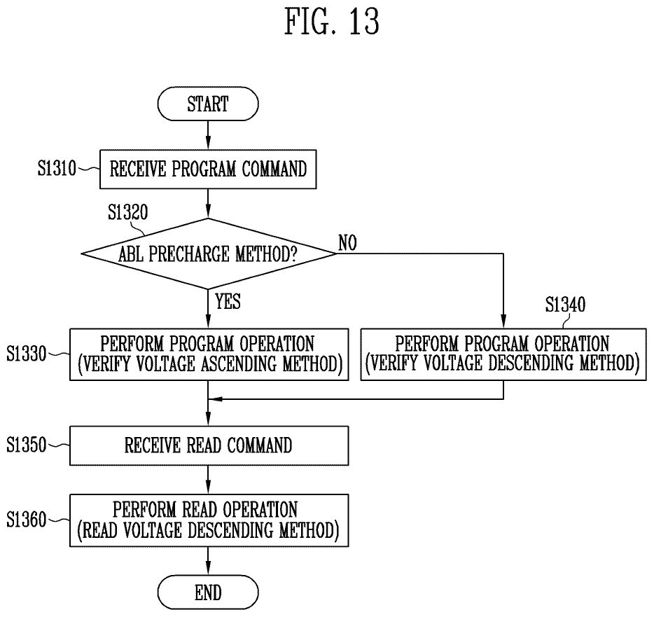

FIG. 13 is a flowchart for describing a program operation and a read operation of a memory device according to an embodiment of the present disclosure.

At operation S1310, the memory controller 200 may generate and output a program command for controlling a program operation of the memory device 100 according to a request from the host 300, and the memory device 100 may receive the program command from the memory controller 200. The memory controller 200 may provide the program command, a physical block address, and data to the memory device 100.

At operation S1320, the verify method determiner 131 of the memory device 100 determines whether a method of precharging bit lines is an ABL precharge method during a program verify operation. For example, when it is determined that the method of precharging bit lines is the ABL precharge method during the program verify operation, the verify method determiner 131 may determine to use a verify voltage ascending method during a program verify operation of a program operation to be subsequently performed. On the other hand, when it is determined that the method of precharging bit lines during the program verify operation is a method of selectively precharging only some bit lines rather than the ABL precharge method, the verify method determiner 131 may determine to use a verify voltage descending method during the program verify operation of the program operation to be subsequently performed.

At the above-described operation S1320, when it is determined that the method of precharging bit lines is the ABL precharge method during the program verify operation (i.e., in the case of Yes), the memory device 100 may perform a program operation in response to the received program command at operation S1330, and may perform the program verify operation of the program operation using the verify voltage ascending method.

The first to m-th page buffers PB1 to PBm receive data to be programmed DATA through the data input/output circuit 124 and temporarily store the received data. During the program voltage apply operation, the first to m-th page buffers PB1 to PBm may apply a program-enable voltage (e.g., a ground voltage) or a program-inhibit voltage (e.g., a supply voltage) to the bit lines BL1 to BLm based on the temporarily stored data.

During the program voltage apply operation, the voltage generator 122 may generate and output a program voltage and a pass voltage in response to an operation signal OPSIG.

During the program voltage apply operation, the address decoder 121 may apply the program voltage generated by the voltage generator 122 to a selected word line and apply the pass voltage generated by the voltage generator 122 to unselected word lines.

During the program verify operation, the voltage generator 122 may sequentially generate a plurality of program verify voltages in response to the operation signal OPSIG, and may generate the program verify voltages in the order from a program verify voltage having a low level to a program verify voltage having a high level.

The address decoder 121 may sequentially apply the plurality of program verify voltages generated by the voltage generator 122 to the selected word line and apply the pass voltage generated by the voltage generator 122 to the unselected word lines.

During the program verify operation, the first to m-th page buffers PB1 to PBm may sense data, stored in the selected memory cells, from the selected memory cells through the bit lines BL1 to BLm whenever the program verify voltage is applied to the selected word line. The first to m-th page buffers PB1 to PBm may generate and output a sensing voltage VPB based on the sensed data and the temporarily stored data to be programmed.

During the program verify operation, the sensing circuit 125 may generate a reference current in response to an enable bit signal VRYBIT generated by the control logic 130, and may output a pass signal PASS or a fail signal FAIL to the control logic 130 by comparing a sensing voltage VPB received from the page buffer group 123 with a reference voltage generated by the reference current. For example, the sensing circuit 125 may output the pass signal to the control logic 130 when the level of the sensing voltage VPB is less than the level of the reference voltage. The control logic 130 may determine whether the program operation has passed or failed based on the pass signal PASS or the fail signal FAIL.

At the above-described operation S1320, when it is determined that the method of precharging bit lines is not an ABL precharge method during the program verify operation (i.e., in the case of No), the memory device 100 may perform a program operation in response to the received program command at operation S1340, and may perform the program verify operation of the program operation using the verify voltage descending method.

The first to m-th page buffers PB1 to PBm receive data to be programmed DATA through the data input/output circuit 124 and temporarily store the received data. During the program voltage apply operation, the first to m-th page buffers PB1 to PBm may apply the program-enable voltage (e.g., a ground voltage) or the program-inhibit voltage (e.g., a supply voltage) to the bit lines BL1 to BLm based on the temporarily stored data.

During the program voltage apply operation, the voltage generator 122 may generate and output a program voltage and a pass voltage in response to an operation signal OPSIG.

During the program voltage apply operation, the address decoder 121 may apply the program voltage generated by the voltage generator 122 to a selected word line and apply the pass voltage generated by the voltage generator 122 to unselected word lines.

During the program verify operation, the voltage generator 122 may sequentially generate a plurality of program verify voltages in response to the operation signal OPSIG, and may generate the program verify voltages in the order from a program verify voltage having a high level to a program verify voltage having a low level.

The address decoder 121 may sequentially apply the plurality of program verify voltages generated by the voltage generator 122 to the selected word line and apply the pass voltage generated by the voltage generator 122 to the unselected word lines.

During the program verify operation, the first to m-th page buffers PB1 to PBm may sense data, stored in the selected memory cells, from the selected memory cells through the bit lines BL1 to BLm whenever the program verify voltage is applied to the selected word line. The first to m-th page buffers PB1 to PBm may generate and output a sensing voltage VPB based on the sensed data and the temporarily stored data to be programmed.

During the program verify operation, the sensing circuit 125 may generate a reference current in response to an enable bit signal VRYBIT generated by the control logic 130, and may output a pass signal PASS or a fail signal FAIL to the control logic 130 by comparing a sensing voltage VPB received from the page buffer group 123 with a reference voltage generated by the reference current. For example, the sensing circuit 125 may output the pass signal to the control logic 130 when the level of the sensing voltage VPB is less than the level of the reference voltage. The control logic 130 may determine whether the program operation has passed or failed based on the pass signal PASS or the fail signal FAIL.

After the above-described program operation (the operation S1330 or S1340) is terminated, the memory controller 200 may generate and output a read command for controlling a read operation of the memory device 100 according to a request from the host 300, and the memory device 100 may receive the read command from the memory controller 200 at operation S1350. The memory controller 200 may provide the read command and a physical block address to the memory device 100.

At operation S1360, the memory device 100 may perform a read operation in response to the received read command.

The verify method determiner 131 of the memory device 100 may control the peripheral circuit 120 to perform the read operation using a read voltage descending method in which a plurality of read voltages are applied in the order from a read voltage having a high level to a read voltage having a low level.

For example, during the read operation, the voltage generator 122 may sequentially generate the plurality of read voltages in response to the operation signal OPSIG, and may generate the read voltages in the order from a read voltage having a high level to a read voltage having a low level.

The address decoder 121 may sequentially apply the plurality of read voltages generated by the voltage generator 122 to the selected word line and apply the pass voltage generated by the voltage generator 122 to the unselected word lines.

The first to m-th page buffers PB1 to PBm may sense data stored in the memory cells from the selected memory cells through the bit lines BL1 to BLm whenever a read verify voltage is applied to the selected word line, and may output the sensed data to the memory controller 200 through the data input/output circuit 124.

As described above, the method of operating the memory device according to an embodiment of the present disclosure may apply a plurality of program verify voltages using the verify voltage ascending method when the bit lines are precharged using an ABL precharge operation method during the program verify operation of the program operation. On the other hand, when the method may apply the plurality of program verify voltages using the verify voltage descending method when the bit lines are precharged using another method other than the ABL precharge operation method.

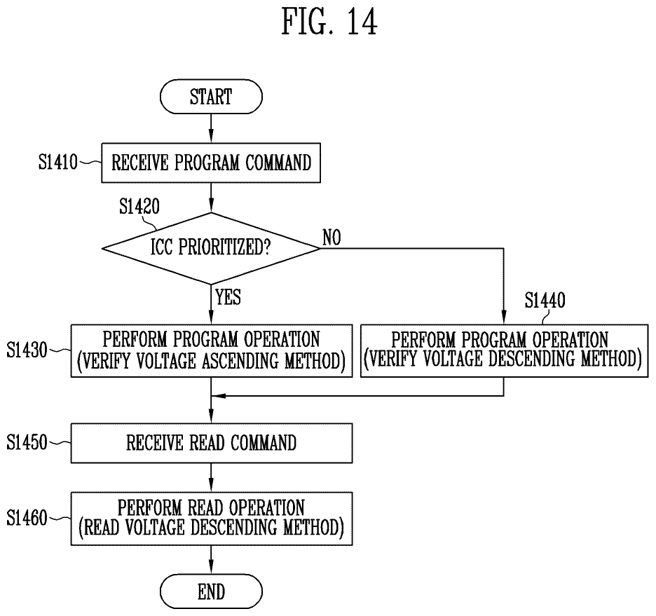

FIG. 14 is a flowchart for describing a program operation and a read operation of a memory device according to an embodiment of the present disclosure.

At operation S1410, the memory controller 200 may generate and output a program command for controlling a program operation of the memory device 100 according to a request from the host 300, and the memory device 100 may receive the program command from the memory controller 200. The memory controller 200 may provide the program command, a physical block address, and data to the memory device 100.

At operation S1420, the verify method determiner 131 may determine whether the program operation of the memory device 100 prioritizes ICC reduction or the operation performance of the program operation, for example, reduction of a program operation time. This process shows that, when a command corresponding to ICC reduction of the memory device 100 is received from the host 300, ICC reduction may be determined to be prioritized, whereas when a command corresponding to ICC reduction is not received, reduction of the program operation time may be determined to be prioritized. When the command corresponding to ICC reduction is received from the host 300, the memory device 100 may be operated in an ICC priority mode, whereas when the command corresponding to ICC reduction is not received, the memory device 100 may be operated in an operation performance priority mode.

In an embodiment, in a case where a command is received from the host 300 to reduce ICC of the memory device 100, the verify method determiner 131 may determine to perform the program verify operation using the above-described verify voltage ascending method. On the other hand, in a case where a command is received from the host 300 to improve the performance of the memory device 100, the verify method determiner 131 may determine to perform the program verify operation using the above-described verify voltage descending method.

At the above-described operation S1420, when it is determined that ICC reduction is prioritized (i.e., in the case of Yes), the memory device 100 may perform a program operation in response to the received program command at operation S1430, and may perform the program verify operation of the program operation using the verify voltage ascending method. That is, when the memory device 100 is operated in the ICC priority mode, the program verify operation of the program operation may be performed using the verify voltage ascending method.

The first to m-th page buffers PB1 to PBm receive data to be programmed DATA through the data input/output circuit 124 and temporarily store the received data. During the program voltage apply operation, the first to m-th page buffers PB1 to PBm may apply the program-enable voltage (e.g., a ground voltage) or the program-inhibit voltage (e.g., a supply voltage) to the bit lines BL1 to BLm based on the temporarily stored data.

During the program voltage apply operation, the voltage generator 122 may generate and output a program voltage and a pass voltage in response to an operation signal OPSIG.

During the program voltage apply operation, the address decoder 121 may apply the program voltage generated by the voltage generator 122 to a selected word line and apply the pass voltage generated by the voltage generator 122 to unselected word lines.

During the program verify operation, the voltage generator 122 may sequentially generate a plurality of program verify voltages in response to the operation signal OPSIG, and may generate the program verify voltages in the order from a program verify voltage having a low level to a program verify voltage having a high level.

The address decoder 121 may sequentially apply the plurality of program verify voltages generated by the voltage generator 122 to the selected word line and apply the pass voltage generated by the voltage generator 122 to the unselected word lines.

During the program verify operation, the first to m-th page buffers PB1 to PBm may sense data, stored in the selected memory cells, from the selected memory cells through the bit lines BL1 to BLm whenever the program verify voltage is applied to the selected word line. The first to m-th page buffers PB1 to PBm may generate and output a sensing voltage VPB based on the sensed data and the temporarily stored data to be programmed.

During the program verify operation, the sensing circuit 125 may generate a reference current in response to an enable bit signal VRYBIT generated by the control logic 130, and may output a pass signal PASS or a fail signal FAIL to the control logic 130 by comparing a sensing voltage VPB received from the page buffer group 123 with a reference voltage generated by the reference current. For example, the sensing circuit 125 may output the pass signal to the control logic 130 when the level of the sensing voltage VPB is less than the level of the reference voltage. The control logic 130 may determine whether the program operation has passed or failed based on the pass signal PASS or the fail signal FAIL.

At the above-described operation S1420, when it is determined that ICC reduction is not prioritized, that is, when it is determined that the program operation performance (e.g., operation speed) of the memory device is prioritized (i.e., in the case of No), the memory device 100 may perform a program operation in response to the received program command at operation S1440, and may perform the program verify operation of the program operation using the verify voltage descending method. That is, when the memory device 100 is operated in the operation performance priority mode, the program verify operation of the program operation may be performed depending on the verify voltage descending method.

The first to m-th page buffers PB1 to PBm receive data to be programmed DATA through the data input/output circuit 124 and temporarily store the received data. During the program voltage apply operation, the first to m-th page buffers PB1 to PBm may apply the program-enable voltage (e.g., a ground voltage) or the program-inhibit voltage (e.g., a supply voltage) to the bit lines BL1 to BLm based on the temporarily stored data.

During the program voltage apply operation, the voltage generator 122 may generate and output a program voltage and a pass voltage in response to an operation signal OPSIG.

During the program voltage apply operation, the address decoder 121 may apply the program voltage generated by the voltage generator 122 to a selected word line and apply the pass voltage generated by the voltage generator 122 to unselected word lines.

During the program verify operation, the voltage generator 122 may sequentially generate a plurality of program verify voltages in response to the operation signal OPSIG, and may generate the program verify voltages in the order from a program verify voltage having a high level to a program verify voltage having a low level.

The address decoder 121 may sequentially apply the plurality of program verify voltages generated by the voltage generator 122 to the selected word line and apply the pass voltage generated by the voltage generator 122 to the unselected word lines.

During the program verify operation, the first to m-th page buffers PB1 to PBm may sense data, stored in the selected memory cells, from the selected memory cells through the bit lines BL1 to BLm whenever the program verify voltage is applied to the selected word line. The first to m-th page buffers PB1 to PBm may generate and output a sensing voltage VPB based on the sensed data and the temporarily stored data to be programmed.

During the program verify operation, the sensing circuit 125 may generate a reference current in response to an enable bit signal VRYBIT generated by the control logic 130, and may output a pass signal PASS or a fail signal FAIL to the control logic 130 by comparing a sensing voltage VPB received from the page buffer group 123 with a reference voltage generated by the reference current. For example, the sensing circuit 125 may output the pass signal to the control logic 130 when the level of the sensing voltage VPB is less than the level of the reference voltage. The control logic 130 may determine whether the program operation has passed or failed based on the pass signal PASS or the fail signal FAIL.

After the above-described program operation (the operation S1430 or S1440) is terminated, the memory controller 200 may generate and output a read command for controlling a read operation of the memory device 100 according to a request from the host 300, and the memory device 100 may receive the read command from the memory controller 200 at operation S1450. The memory controller 200 may provide the read command and a physical block address to the memory device 100.

At operation S1460, the memory device 100 may perform a read operation in response to the received read command.

The verify method determiner 131 of the memory device 100 may control the peripheral circuit 120 to perform the read operation using a read voltage descending method in which a plurality of read voltages are applied in the order from a read voltage having a high level to a read voltage having a low level.

For example, during the read operation, the voltage generator 122 may sequentially generate the plurality of read voltages in response to the operation signal OPSIG, and may generate the read voltages in the order from a read voltage having a high level to a read voltage having a low level.

The address decoder 121 may sequentially apply the plurality of read voltages generated by the voltage generator 122 to the selected word line and apply the pass voltage generated by the voltage generator 122 to the unselected word lines.

The first to m-th page buffers PB1 to PBm may sense data stored in the memory cells from the selected memory cells through the bit lines BL1 to BLm whenever a read verify voltage is applied to the selected word line, and may output the sensed data to the memory controller 200 through the data input/output circuit 124.

As described above, in the method of operating the memory device according to an embodiment of the present disclosure, when a command for prioritizing ICC is received from the host, a plurality of program verify voltages may be applied using the verify voltage ascending method during the program verify operation of the program operation. On the other hand, when the command for prioritizing ICC is not received from the host, the plurality of program verify voltages may be applied using the verify voltage descending method during the program verify operation.

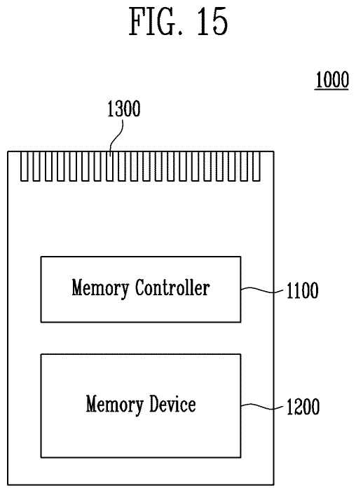

FIG. 15 is a block diagram illustrating a memory card system 1000 including a memory system according to an embodiment of the present disclosure.

Referring to FIG. 15, the memory card system 1000 may include a memory controller 1100, a memory device 1200, and a connector 1300.

The memory controller 1100 is connected to the memory device 1200. The memory controller 1100 may access the memory device 1200. For example, the memory controller 1100 may control read, write, erase, and background operations of the memory device 1200. The memory controller 1100 may provide an interface between the memory device 1200 and a host. The memory controller 1100 may run firmware for controlling the memory device 1200. The memory controller 1100 may be implemented in the same manner as the memory controller 200, described above with reference to FIG. 1. The memory device 1200 may be implemented in the same manner as the memory device 100, described above with reference to FIG. 1.

In an embodiment, the memory controller 1100 may include components, such as a random access memory (RAM), a processor, a host interface, a memory interface, and an error correction circuit.

The memory controller 1100 may communicate with an external device (e.g., a host) through the connector 1300. The memory controller 1100 may communicate with an external device based on a specific communication standard. In an embodiment, the memory controller 1100 may communicate with the external device through at least one of various communication standards or interfaces such as universal serial bus (USB), multimedia card (MMC), embedded MMC (eMMC), peripheral component interconnection (PCI), PCI-express (PCI-E), an advanced technology attachment (ATA) protocol, a serial-ATA (SATA), parallel-ATA (PATA), small computer system interface (SCSI), enhanced small disk interface (ESDI), integrated drive electronics (IDE), Firewire, universal flash storage (UFS), WiFi, Bluetooth, and nonvolatile memory express (NVMe) protocols. In an embodiment, the connector 1300 may be defined by at least one of the above-described various communication standards.

In an embodiment, the memory device 1200 may be implemented as any of various nonvolatile memory devices, such as an electrically erasable and programmable ROM (EEPROM), a NAND flash memory, a NOR flash memory, a phase-change RAM (PRAM), a resistive RAM (ReRAM), a ferroelectric RAM (FRAM), and a spin transfer torque magnetic RAM (STT-MRAM).

The memory controller 1100 and the memory device 1200 may be integrated into a single semiconductor device to form a memory card. For example, the memory controller 1100 and the memory device 1200 may be integrated into a single semiconductor device to form a memory card such as a personal computer memory card international association (PCMCIA), a compact flash card (CF), a smart media card (SM or SMC), a memory stick, a multimedia card (MMC, RS-MMC, MMCmicro or eMMC), an SD card (SD, miniSD, microSD, or SDHC), or a universal flash storage (UFS).

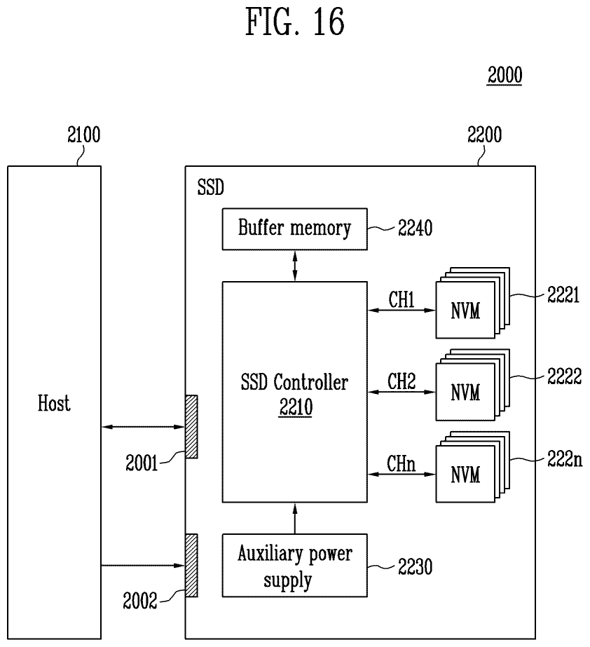

FIG. 16 is a block diagram illustrating a solid state drive (SSD) system 2000 including a memory system according to an embodiment of the present disclosure.

Referring to FIG. 16, the SSD system 2000 may include a host 2100 and an SSD 2200. The SSD 2200 may exchange signals with the host 2100 through a signal connector 2001, and may receive power through a power connector 2002. The SSD 2200 may include an SSD controller 2210, a plurality of flash memories 2221 to 222n, an auxiliary power supply 2230, and a buffer memory 2240.

In accordance with an embodiment of the present disclosure, the SSD controller 2210 may perform the function of the memory controller 200, described above with reference to FIG. 1.

The SSD controller 2210 may control the plurality of flash memories 2221 to 222n in response to the signals received from the host 2100. In an embodiment, the signals may be signals based on the interfaces of the host 2100 and the SSD 2200. For example, the signals may be signals defined by at least one of communication standards or interfaces such as universal serial bus (USB), multimedia card (MMC), embedded MMC (eMMC), peripheral component interconnection (PCI), PCI-express (PCI-E), advanced technology attachment (ATA), serial-ATA (SATA), parallel-ATA (PATA), small computer system interface (SCSI), enhanced small disk interface (ESDI), integrated drive electronics (IDE), Firewire, universal flash storage (UFS), WiFi, Bluetooth, and nonvolatile memory express (NVMe).

The auxiliary power supply 2230 may be connected to the host 2100 through the power connector 2002. The auxiliary power supply 2230 may be supplied with power from the host 2100, and may be charged. The auxiliary power supply 2230 may supply the power to the SSD 2200 when the supply of power from the host 2100 is not smoothly performed. In an embodiment, the auxiliary power supply 2230 may be located inside the SSD 2200 or located outside the SSD 2200. For example, the auxiliary power supply 2230 may be located on a main board, and may provide auxiliary power to the SSD 2200.

The buffer memory 2240 functions as a buffer memory of the SSD 2200. For example, the buffer memory 2240 may temporarily store data received from the host 2100 or data received from the plurality of flash memories 2221 to 222n or may temporarily store metadata (e.g., mapping tables) of the flash memories 2221 to 222n. The buffer memory 2240 may include volatile memories, such as DRAM, SDRAM, DDR SDRAM, LPDDR SDRAM, and GRAM, or nonvolatile memories, such as FRAM, ReRAM, STT-MRAM, and PRAM.

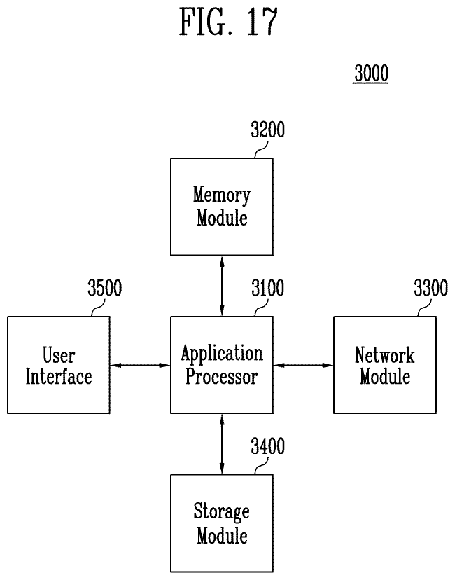

FIG. 17 is a block diagram illustrating a user system including a memory system 3000 according to an embodiment of the present disclosure.

Referring to FIG. 17, the user system 3000 may include an application processor 3100, a memory module 3200, a network module 3300, a storage module 3400, and a user interface 3500.

The application processor 3100 may run components included in the user system 3000, an operating system (OS) or a user program. In an embodiment, the application processor 3100 may include controllers, interfaces, graphic engines, etc. for controlling the components included in the user system 3000. The application processor 3100 may be provided as a system-on-chip (SoC).

The memory module 3200 may function as a main memory, a working memory, a buffer memory or a cache memory of the user system 3000. The memory module 3200 may include volatile RAMs such as DRAM, SDRAM, DDR SDRAM, DDR2 SDRAM, DDR3 SDRAM, LPDDR SDRAM, LPDDR2 SDRAM, and LPDDR3 SDRAM, or nonvolatile RAMs such as PRAM, ReRAM, MRAM, and FRAM. In an embodiment, the application processor 3100 and the memory module 3200 may be packaged based on a package-on-package (POP), and may then be provided as a single semiconductor package.

The network module 3300 may communicate with external devices. In an embodiment, the network module 3300 may support wireless communication, such as code division multiple access (CDMA), a global system for mobile communication (GSM), wideband CDMA (WCDMA), CDMA-2000, time division multiple access (TDMA), long term evolution (LTE), WiMAX, WLAN, UWB, Bluetooth, or Wi-Fi. In an embodiment, the network module 3300 may be included in the application processor 3100.

The storage module 3400 may store data. For example, the storage module 3400 may store data received from the application processor 3100. Alternatively, the storage module 3400 may transmit the data stored in the storage module 3400 to the application processor 3100. In an embodiment, the storage module 3400 may be implemented as a nonvolatile semiconductor memory device, such as a phase-change RAM (PRAM), a magnetic RAM (MRAM), a resistive RAM (RRAM), a NAND flash memory, a NOR flash memory, or a NAND flash memory having a three-dimensional (3D) structure. In an embodiment, the storage module 3400 may be provided as a removable storage medium (removable drive), such as a memory card or an external drive of the user system 3000.

In an embodiment, the storage module 3400 may include a plurality of nonvolatile memory devices, each of which may be operated in the same manner as the memory device 100, described above with reference to FIG. 1. The storage module 3400 may be operated in the same manner as the memory system 50, described above with reference to FIG. 1.

The user interface 3500 may include interfaces which input data or instructions to the application processor 3100 or output data to external devices. In an embodiment, the user interface 3500 may include user input interfaces such as a keyboard, a keypad, a button, a touch panel, a touch screen, a touch pad, a touch ball, a camera, a microphone, a gyroscope sensor, a vibration sensor, and a piezoelectric element. The user interface 3500 may include user output interfaces such as an a liquid crystal display (LCD), an organic light emitting diode (OLED) display device, an active matrix OLED (AMOLED) display device, an LED, a speaker, and a monitor.

According to the embodiments of the present disclosure, the order of application of a plurality of program verify voltages is set during a program verify operation, and thus the threshold voltage distributions of memory cells may be improved, internal current consumption of the memory device may be reduced, and the operation performance of the memory device may be enhanced. Furthermore, the embodiments may be combined to form additional embodiments.

What is claimed is:

1. A memory device comprising:
a memory block connected to a plurality of word lines;
a voltage generator configured to generate, during a program operation on the memory block, a program voltage and a plurality of program verify voltages to be applied to a selected word line among the plurality of word lines, and generate, during a read operation on the memory block, a plurality of read voltages to be applied to the selected word line; and
a control logic configured to control the voltage generator,
wherein, during a program verify operation of the program operation, the voltage generator is configured to generate the plurality of program verify voltages according to a verify voltage ascending method in which the plurality of program verify voltages are sequentially generated in an order from a program verify voltage having a low level to a program verify voltage having a high level, and
wherein, during the read operation, the voltage generator is configured to generate the plurality of read voltages according to a read voltage descending method in which the plurality of read voltages are sequentially generated in an order from a read voltage having a high level to a read voltage having a low level.

2. The memory device according to claim 1, wherein the control logic comprises a verify method determiner configured to control, during the program verify operation, the voltage generator to generate the plurality of program verify voltages according to the verify voltage ascending method.

3. The memory device according to claim 2, wherein, during the read operation, the verify method determiner is configured to control the voltage generator to generate the plurality of read voltages according to the read voltage descending method.

4. The memory device according to claim 2, wherein, when all bit lines of a plurality of bit lines connected to the memory block are simultaneously precharged during a bit line precharge operation of precharging the plurality of bit lines while the program verify operation is performed, the verify method determiner is configured to control the voltage generator to generate the plurality of program verify voltages according to the verify voltage ascending method.

5. The memory device according to claim 4, wherein, when some bit lines of the plurality of bit lines are selectively precharged during the bit line precharge operation, the verify method determiner is configured to control the voltage generator to generate the plurality of program verify voltages according to a verify voltage descending method in which the plurality of program verify voltages are sequentially generated in an order from the program verify voltage having the high level to the program verify voltage having the low level.

6. The memory device according to claim 2, wherein the verify method determiner is configured to control the voltage generator to generate the plurality of program verify voltages according to the verify voltage ascending method.

7. The memory device according to claim 6, wherein, in an internal current consumption (ICC) priority mode, the verify method determiner is configured to control the voltage generator to generate the plurality of program verify voltages according to a verify voltage descending method.

8. A method of operating a memory device, the method comprising:
performing a program operation of sequentially performing a plurality of program loops, each including a program voltage apply operation and a program verify operation, on selected memory cells in response to a program command; and
performing a read operation on the selected memory cells in response to a read command after the program operation is completed,
wherein, during the program verify operation, a plurality of program verify voltages are applied to the selected memory cells according to a verify voltage ascending method in which the plurality of program verify voltages are sequentially applied to the selected memory cells in an order from a program verify voltage having a low level to a program verify voltage having a high level, and
wherein, during the read operation, a plurality of read voltages are applied to the selected memory cells according to a read voltage descending method in which the plurality of read voltages are sequentially applied to the selected memory cells in an order from a read voltage having a high level to a read voltage having a low level.

9. A method of operating a memory device, the method comprising:
performing a program operation of sequentially performing a plurality of program loops, each including a program voltage apply operation and a program verify operation, on selected memory cells in response to a program command; and
performing a read operation on the selected memory cells in response to a read command after the program operation is completed,
wherein, in response to a case in which all bit lines connected to the selected memory cells are simultaneously precharged during a bit line precharge operation of precharging the bit lines while the program verify operation is performed, a plurality of program verify voltages are applied to the selected memory cells according to a verify voltage ascending method in which the plurality of program verify voltages are sequentially applied to the selected memory cells in an order from a program verify voltage having a low level to a program verify voltage having a high level, and
wherein, in response to a case in which part of the bit lines are selectively precharged during the bit line precharge operation, the plurality of program verify voltages are applied to the selected memory cells according to a verify voltage descending method in which the plurality of program verify voltages are sequentially applied to the selected memory cells in an order from the program verify voltage having the high level to the program verify voltage having the low level.

10. The method according to claim 9, wherein, during the read operation, a plurality of read voltages are applied to the selected memory cells according to a read voltage descending method in which the plurality of read voltages are sequentially applied to the selected memory cells in an order from a read voltage having a high level to a read voltage having a low level.

11. A method of operating a memory device, the method comprising:
performing a program operation of sequentially performing a plurality of program loops, each including a program voltage apply operation and a program verify operation, on selected memory cells in response to a program command; and
performing a read operation on the selected memory cells in response to a read command after the program operation is completed,
wherein, in response to a case in which the program operation is performed in an internal current consumption (ICC) priority mode, a plurality of program verify voltages are applied, during the program verify operation, to the selected memory cells according to a verify voltage ascending method in which the plurality of program verify voltages are sequentially applied to the selected memory cells in an order from a program verify voltage having a low level to a program verify voltage having a high level, and
wherein, in response to a case in which the program operation is performed in an operation performance priority mode, the plurality of program verify voltages are applied, during the program verify operation, to the selected memory cells according to a verify voltage descending method in which the plurality of program verify voltages are sequentially applied to the selected memory cells in an order from the program verify voltage having the high level to the program verify voltage having the low level.

12. The method according to claim 11, wherein, during the read operation, a plurality of read voltages are applied to the selected memory cells according to a read voltage descending method in which the plurality of read voltages are sequentially applied to the selected memory cells in an order from a read voltage having a high level to a read voltage having a low level.
